(19) United States
(12) Patent Application Publication
(10) Pub. No.: US 2025/0087538 A1
(43) Pub. Date: Mar. 13, 2025

(54) SEMICONDUCTOR DEVICE

(71) Applicant: Samsung Electronics Co., Ltd., Suwon-si (KR)

(72) Inventor: Myeonghoon HONG, Suwon-si (KR)

(73) Assignee: Samsung Electronics Co., Ltd., Suwon-si (KR)

(21) Appl. No.: 18/595,689

(22) Filed: Mar. 5, 2024

(30) Foreign Application Priority Data
Sep. 13, 2023 (KR) 10-2023-0121807

(51) Int. Cl. H01L 21/66; H01L 23/00; H01L 23/532; H10B 41/41

(52) U.S. Cl. CPC H01L 22/34; H01L 22/12; H01L 23/53271; H01L 23/562; H10B 41/41

(57) ABSTRACT

A semiconductor device may include a semiconductor substrate having a first surface including a memory cell area; a first chipping detection circuit on the first surface of the semiconductor substrate and surrounding the memory cell area; and a chip guard on the first surface of the semiconductor substrate. A portion of the chip guard may overlap the first chipping detection circuit in a direction perpendicular to the first surface of the semiconductor substrate.

### CROSS-REFERENCE TO RELATED APPLICATION

This application claims priority to and the benefit of Korean Patent Application No. 10-2023-0121807, filed in the Korean Intellectual Property Office on Sep. 13, 2023, the entire contents of which are incorporated herein by reference.

### BACKGROUND

### (a) Field

The present disclosure relates to a semiconductor device.

### (b) Description of the Related Art

In the process of manufacturing a semiconductor device, for example, stress occurring in a cutting process and a heating process may cause defects in the semiconductor chip, such as cracks.

Various methods are proposed to detect the defects occurring in the semiconductor chips during the process, and one of them is to dispose a detection wire at the edge portion of the semiconductor chip and to detect defects occurring in semiconductor chips using the disposed detection wire.

However, as the structure of semiconductor devices becomes more complex and diversified, the manufacturing process of semiconductor devices may be complicated and the size of semiconductor devices may also increase when these defect (or chipping) detection elements are disposed on each semiconductor chip that configures the semiconductor device. Therefore, efficient disposition of defect (or chipping) detection elements may be required.

### SUMMARY

Embodiments of the present disclosure may provide a semiconductor device in which a defect detection element is efficiently disposed.

Embodiments of the present disclosure may reduce the size of a semiconductor device including a defect (or chipping) detection element.

According to an embodiment, a semiconductor device may include a semiconductor substrate having a first surface including a memory cell area; a first chipping detection circuit on the first surface of the semiconductor substrate and surrounding the memory cell area; and a chip guard on the first surface of the semiconductor substrate, wherein a portion of the chip guard may overlap the first chipping detection circuit in a direction perpendicular to the first surface of the semiconductor substrate.

According to an embodiment, a semiconductor device may include a semiconductor substrate having a first surface including a memory cell area; a first chipping detection circuit on the first surface of the semiconductor substrate and surrounding the memory cell area; a chip guard on the first surface of the semiconductor substrate and around the memory cell area; a chip dam on the first surface of the semiconductor substrate, the chip dam surrounding the first chipping detection circuit and the chip guard; and a second chipping detection circuit on the first surface of the semiconductor substrate. The second chipping detection circuit may be between the first chipping detection circuit and the chip guard and between the first chipping detection circuit and the chip dam. The first chipping detection circuit may include a lower structure separated into a plurality of portions and an upper structure connecting the plurality of portions of the lower structure to each other. The chip guard may have a plurality of portions separated from each other. The plurality of portions of the chip guard may be alternately disposed with the lower structure of the first chipping detection circuit. The plurality of portions of the chip guard may overlap the upper structure of the first chipping detection circuit in a direction perpendicular to the first surface.

According to an embodiment, a semiconductor device may include a first semiconductor substrate including a memory cell driving circuit; a second semiconductor substrate bonded to the first semiconductor substrate and including a memory cell area; a first chipping detection circuit between the first semiconductor substrate and the second semiconductor substrate and surrounding a memory cell area; a chip guard between the first semiconductor substrate and the second semiconductor substrate, a portion of the chip guard overlapping the first chipping detection circuit in a direction perpendicular to the first semiconductor substrate and the second semiconductor substrate; and an arc path diode connected between the first chipping detection circuit and the first semiconductor substrate. The first chipping detection circuit may include a lower structure separated into a plurality of portions and an upper structure connecting the plurality of portions of the lower structure to each other. The lower structure of the first chipping detection circuit may include a chipping detection circuit gate on the first semiconductor substrate, a plurality of chipping detection circuit wires on the chipping detection circuit gate, and a plurality of chipping detection circuit vias connecting the chipping detection circuit gate and the plurality of chipping detection circuit wires. The upper structure of the first chipping detection circuit may include a chipping detection circuit connection wire and a chipping detection circuit connection via. The chipping detection circuit connection wire may span between at least two of the plurality of portions of the lower structure. The chipping detection circuit connection via may connect the lower structure and the chipping detection circuit connection wire. The chip guard may include a chip guard doped area near the first surface of the first semiconductor substrate, a chip guard wire on the chip guard doped area, and a chip guard via connecting the chip guard doped area and the chip guard wire.

In some example embodiments, the size of a semiconductor device may be reduced by overlapping a chipping detection circuit (CDC) and a chip guard.

In some example embodiments, a chipping detection circuit and an arc path diode may be disposed between chip guards to protect a semiconductor device from arcs being introduced from the outside or occurring at an edge of a chip.

### BRIEF DESCRIPTION OF THE DRAWINGS

FIG. 1 illustrates a layout view of a semiconductor device according to an embodiment.

FIG. 2 illustrates a cross-sectional view taken along line A-A′ of FIG. 1.

FIG. 3 illustrates a cross-sectional view of a semiconductor device according to another embodiment, and corresponds to a cross-sectional view taken along line A-A′ in FIG. 1.

FIG. 4 illustrates a cross-sectional view of a semiconductor device according to another embodiment.

FIG. 5 illustrates a layout view of portion B of FIG. 4 viewed from above.

FIG. 6 illustrates a cross-sectional view of a semiconductor device according to another embodiment.

FIG. 7 illustrates a layout view of portion C of FIG. 6 viewed from above.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

The drawings and the descriptions are to be considered in an illustrative sense and not as restrictive. Throughout the specification, the same reference numbers indicate the same constituent elements.

In the drawings, the size and thickness of each constituent element may be shown for better understanding and ease of description, and the present disclosure is not necessarily limited to what is shown in the drawings. In the drawings, the thickness of layers, films, plates, panels, regions, areas, and the like may be exaggerated for clarity. In the drawings, the thickness of some layers, areas, and regions may be exaggerated for better understanding and ease of description.

As used herein, the singular forms (for example, a, an, and the) are intended to include the plural forms as well (and vice versa), unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the present disclosure.

When an element, such as a layer, a film, a region, an area, or a substrate is described to be “above” another element, it may be directly above another element or there may be an intermediate element. In contrast, when a first element is described to be “directly above” a second element, there is no intermediate element. Throughout the specification, the term “above” a target must be “understood as being disposed above or below the target element, and does not necessarily signify “above” with respect to an opposite direction of gravity.

For example, spatially relative terms “below” or “above” may be used to facilitate the description of the relationship of one element or a constituent element to other constituent elements as shown in the drawings. The spatially relative terms are intended to include other directions in use or operation in addition to the directions shown in the drawings. For example, when the device shown in the drawing is flipped, the device disposed below another device may be disposed “above” the other device. Therefore, the exemplary term “below” may include lower and upper positions. The device may also be oriented in other directions, the spatially relative term may be analyzed differently depending on the directions.

When an element (or region, area, layer, portion, etc.) is described to be “connected” or “combined” to another element in the specification, it may be directly disposed, connected, or combined on the above-noted other element, or an element may be disposed therebetween.

The term “connected to” or “combined to” may include physical or electrical connections or combinations.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

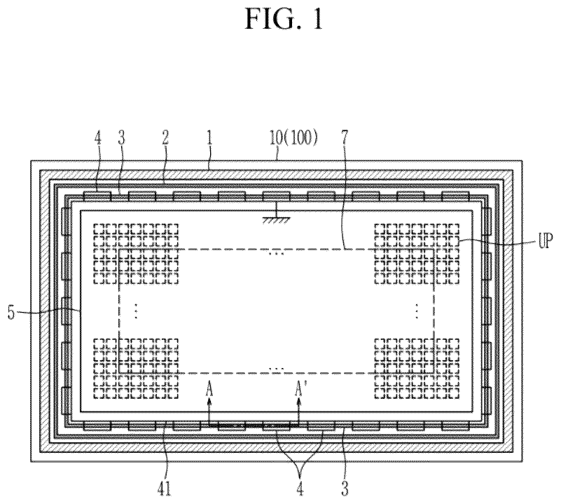

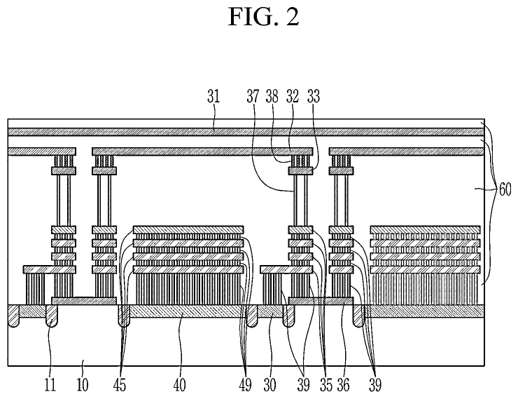

FIG. 1 illustrates a layout view of a semiconductor device (chip) according to an embodiment. FIG. 2 illustrates a cross-sectional view taken along line A-A′ of FIG. 1. The present embodiment may relate to a chip-on-Perri VNAND (COP VNAND) structure in which a peripheral driving circuit 7 of a vertical NAND flash memory is disposed under a memory cell UP.

Referring to FIG. 1 and FIG. 2, a chip dam 1 may be disposed along an edge of a semiconductor substrate 10 configuring a semiconductor device. The chip dam 1 may be a reinforced structure around a scribing line to limit and/or prevent cracks from spreading inside the semiconductor chip and to allow cutting along the scribing line when dividing the semiconductor chip through scribing. The chip dam 1 may be formed together along with a wire or via for a semiconductor device.

A ring chipping detection circuit 2 may be disposed inside the chip dam 1. The ring chipping detection circuit 2 may be a circuit for detecting a crack intruding into a chip or a physical damage occurred in a chip, and may be referred to as a chipping detection circuit (CDC). The ring chipping detection circuit 2 may also be formed along with a wire or via of a semiconductor device.

A net chipping detection circuit 3 and a chip guard 4 may be disposed inside the ring chipping detection circuit 2. A memory cell area 5 may be disposed inside the net chipping detection circuit 3 and the chip guard 4.

The net chipping detection circuit 3 may also be a circuit for detecting a crack intruding into a chip or a physical damage occurred in a chip, and may be connected to an arc path diode.

The arc path diode is a device for dissipating or discharging an arc when the arc is introduced into the net chipping detection circuit 3 from the outside or the arc occurs inside the chip, and it may include a diode doped area 30 in which the semiconductor substrate 10 is doped with N-type impurities. A shallow trench isolation (STI) 11 may be disposed around the diode doped area 30 to separate the diode doped area 30 from other parts of the semiconductor substrate 10. The semiconductor substrate 10 may be doped with P-type impurities, and thus a PN junction may be formed between the semiconductor substrate 10 and the diode doped area 30. When a driving voltage is applied to the net chipping detection circuit 3, the arc path diode may turned off to block a current from flowing, and when a high voltage due to an arc is applied thereto, it may be destroyed by the arc energy so that the arc energy may be dissipated.

The net chipping detection circuit 3 may include a chipping detection circuit gate 36, a chipping detection circuit wire 35, a chipping detection circuit via 39, chipping detection circuit connection wires 31, 32, and 33, and chipping detection circuit connection vias 37 and 38, disposed on the semiconductor substrate 10. The diode doped area 30 may be connected to the net chipping detection circuit 3 via the chipping detection circuit via 39. The chipping detection circuit gate 36, the chipping detection circuit wire 35, and the chipping detection circuit via 39 may be disposed in the lower layer in which the peripheral driving circuit of the COP VNAND is formed, and may form the lower structure of the net chipping detection circuit 3. The lower structure of the net chipping detection circuit 3 may include a plurality of portions, and these plurality of portions may be disposed spaced apart from each other at desired and/or alternatively predetermined intervals. The lower structure of the net chipping detection circuit 3 may be formed together along with the wire or via of the peripheral driving circuit of the COP VNAND.

The net chipping detection circuit 3 may include an upper structure connecting the lower structures spaced apart from each other at desired and/or alternatively predetermined intervals. The upper structure of the net chipping detection circuit 3 may include the chipping detection circuit connection wires 31, 32, and 33 and the chipping detection circuit connection vias 37 and 38. The connection between the chipping detection circuit connection wires 31, 32, and 33 and the chipping detection circuit connection vias 37 and 38 may be implemented in various forms other than those shown in FIG. 2. The upper structure of the net chipping detection circuit 3 may be formed together along with the wire or via of the memory cell UP portion of the COP VNAND.

The chipping detection circuit gate 36 may include a plurality of layers including a tungsten layer and a polysilicon layer, and the chipping detection circuit wire 35 and the chipping detection circuit connection wires 31, 32, and 33 may include copper or aluminum. The uppermost layer chipping detection circuit connection wire 31 may include aluminum, and the remaining chipping detection circuit connection wires 32 and 33 and the chipping detection circuit wire 35 may include copper. The chipping detection circuit via 39 and the chipping detection circuit connection vias 37 and 38 may be formed of at least one of metals such as tungsten, titanium, tantalum, platinum, cobalt, copper, or aluminum as a main component. The main component refers to a component that accounts for more than half of the total weight.

The chip guard 4 may be disposed so that at least a portion thereof overlaps the net chipping detection circuit 3. The chip guard 4 may maintain the edge of the chip at a ground voltage to protect internal elements of the chip from static electricity and limit and/or prevent latch-up defect from occurring. The chip guard 4 may be distributed into a plurality of portions, and the plurality of portions may be connected to each other through a chip guard connection line 41. In some embodiments, each of the plurality of portions of the chip guard 4 may be connected to a separate ground circuit. The plurality of portions of the chip guard 4 may be disposed alternately with the plurality of portion of the lower structure of the net chipping detection circuit 3, and may overlap the upper structure of the net chipping detection circuit 3 in the vertical direction. The chip guard 4 may be formed together along with the lower structure of the net chipping detection circuit 3. The chip guard connection line 41 may bypass the lower structure of the net chipping detection circuit 3 to connect the distributed plurality of portions of the chip guard 4 to each other. The chip guard connection line 41 may be disposed on the same layer as and may include the same material as a portion of the chipping detection circuit wire 35. That is, the chip guard connection line 41 may be formed together along with a portion of the chipping detection circuit wire 35.

The chip guard 4 may include a chip guard doped area 40 formed by doping the upper portion of the semiconductor substrate 10, and may include a chip guard via 49 and a chip guard wire 45 disposed on the chip guard doped area 40. The chip guard doped area 40 may be doped with P-type impurities.

The chip guard wire 45 may include copper or aluminum. The chip guard via 49 may be formed of at least one of metals such as tungsten, titanium, tantalum, platinum, cobalt, copper, or aluminum as a main component. An interlayer dielectric layer 60 may be formed on the substrate 10 and cover the net chipping detection circuit 3 and chip guard 4.

As described above, the size of the semiconductor device may be reduced by overlapping the chip guard 4 with the net chipping detection circuit 3. By connecting the arc path diode to the chipping detection circuit 3, the semiconductor device may be protected from arcs flowing in from the outside or occurring at the edge of the chip.

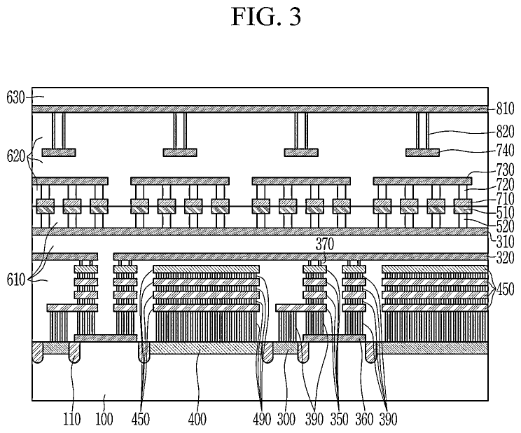

FIG. 3 illustrates a cross-sectional view of a semiconductor device according to another embodiment, and corresponds to a cross-sectional view taken along line A-A′ in FIG. 1. The present embodiment may be a case applied to a bonding VNAND (BVNAND) structure in which a substrate including a peripheral driving circuit 7 and a substrate including a memory cell UP are separately manufactured and bonded.

Referring to FIG. 1 and FIG. 3, it may be the same as in the previous embodiment that the chip dam 1, the ring chipping detection circuit 2, the net chipping detection circuit 3, and the chip guard 4 are sequentially disposed between the edge of the semiconductor substrate 100 and the memory cell area 5. The structures or functions of the chip dam 1 and the ring chipping detection circuit 2 may be the same as the previous embodiment. The functions of the net chipping detection circuit 3 and the chip guard 4 may also be the same as the previous embodiment. The structures of the net chipping detection circuit 3 and the chip guard 4 are different from those of the previous embodiment, and these differences will be mainly described below.

Referring to FIG. 3, an arc path diode connected to the net chipping detection circuit 3 may be included. The arc path diode is a device for dissipating or discharging an arc when the arc is introduced into the net chipping detection circuit 3 from the outside or the arc occurs inside the chip, and it may include a diode doped area 300 in which the semiconductor substrate 100 is doped with N-type impurities. A shallow trench isolation (STI) 110 may be disposed around the diode doped area 300 to separate the diode doped area 300 from other parts of the semiconductor substrate 100. The semiconductor substrate 100 may be doped with P-type impurities, and thus a PN junction may be formed between the semiconductor substrate 100 and the diode doped area 300. When a driving voltage is applied to the net chipping detection circuit 3, the arc path diode may turned off to block a current from flowing, and when a high voltage due to an arc is applied thereto, it may be destroyed by the arc energy so that arc energy may be dissipated.

The net chipping detection circuit 3 may include a chipping detection circuit gate 360, a chipping detection circuit wire 350, a chipping detection circuit via 390, chipping detection circuit connection wires 310 and 320, and a chipping detection circuit connection via 370, disposed on the semiconductor substrate 100. The diode doped area 300 may be connected to the net chipping detection circuit 3 via the chipping detection circuit via 390. The chipping detection circuit gate 360, the chipping detection circuit wire 350, and the chipping detection circuit via 390 may form a lower structure of the net chipping detection circuit 3. The lower structure of the net chipping detection circuit 3 may include a plurality of portions, and the plurality of portions may be disposed spaced apart from each other at desired and/or alternatively predetermined intervals. The lower structure of the net chipping detection circuit 3 may be disposed on a substrate including the peripheral driving circuit 7 of the BVNAND, and may be formed together along with a wire or via of the peripheral driving circuit 7 of the BVNAND.

The net chipping detection circuit 3 may include an upper structure connecting the lower structures spaced apart from each other at desired and/or alternatively predetermined intervals. The upper structure of the net chipping detection circuit 3 may include the chipping detection circuit connection wires 310 and 320, the chipping detection circuit connection via 370, lower and upper bonding pads 510 and 710, bonding pad vias 520 and 720, memory cell substrate wires 730, 740, and 810, a memory cell substrate via 820, and the like. The connection between the chipping detection circuit connection wires 310 and 320, the chipping detection circuit connection via 370, the upper and lower bonding pads 510 and 710, the bonding pad vias 520 and 720, the memory cell substrate wires 730, 740, and 810, and the memory cell substrate via 820 may be implemented in various forms other than the form shown in FIG. 3. In the upper structure of the net chipping detection circuit 3, the chipping detection circuit connection wires 310 and 320, the chipping detection circuit connection via 370, the lower bonding pad 510, and the lower bonding pad via 520 may be disposed on the substrate including the peripheral driving circuit of the BVNAND, and may be formed together along with the wire or via of the peripheral driving circuit 7 of the BVNAND. In the upper structure of the net chipping detection circuit 3, the remaining upper bonding pad 710, the upper bonding pad via 720, the memory cell substrate wires 730, 740, and 810, the memory cell substrate via 820, and the like may be disposed on a substrate including a memory cell UP of the BVNAND, and may be formed together along with a wire or via of the memory cell UP. An interlayer dielectric layer 610 may be formed on the substrate 100 and cover parts of the net chipping detection circuit 3 and chip guard 4. An interlayer dielectric layer 620 may be formed on the interlayer dielectric layer 610 and cover the upper bonding bods 710, memory cell substrate wires 730 and 740, and memory cell substrate via 820. An interlayer dielectric layer 630 may be formed over the memory cell substrate wire 810.

The chipping detection circuit gate 360 may include a plurality of layers including a tungsten layer and a polysilicon layer, and the chipping detection circuit wire 350, the chipping detection circuit connection wires 310 and 320, and the memory cell substrate wires 730, 740, and 810 may include copper or aluminum. The chipping detection circuit via 390, the chipping detection circuit connection via 370, the lower and upper bonding pads 510 and 710, the bonding pad part vias 520 and 720, and the memory cell substrate via 820 may be formed of at least one of metals such as tungsten, titanium, tantalum, platinum, cobalt, copper, or aluminum as a main component. The main component refers to a component that accounts for more than half of the total weight.

The chip guard 4 may be disposed so that at least a portion thereof overlaps the net chipping detection circuit 3. The chip guard 4 may be distributed into a plurality of portions, and the plurality of portions may be connected to each other through the chip guard connection line 41. In some embodiments, each of the plurality of portions of the chip guard 4 may be connected to a separate ground circuit. The plurality of portions of the chip guard 4 may be disposed alternately with the plurality of portion of the lower structure of the net chipping detection circuit 3, and may overlap the upper structure of the net chipping detection circuit 3 in the vertical direction. The chip guard 4 may be formed together along with the lower structure of the net chipping detection circuit 3. The chip guard connection line 41 may bypass the lower structure of the net chipping detection circuit 3 to connect the distributed plurality of portions of the chip guard 4 to each other. The chip guard connection line 41 may be disposed on the same layer as and may include the same material as a portion of the chipping detection circuit wire 350. That is, the chip guard connection line 41 may be formed together along with a portion of the chipping detection circuit wire 350.

The chip guard 4 may include a chip guard doped area 400 formed by doping the upper portion of the semiconductor substrate 10, and may include a chip guard via 490 and a chip guard wire 450 disposed on the chip guard doped area 400. The chip guard doped area 400 may be doped with P-type impurities.

The chip guard wire 450 may include copper or aluminum. The chip guard via 490 may be formed of at least one of metals such as tungsten, titanium, tantalum, platinum, cobalt, copper, or aluminum as a main component.

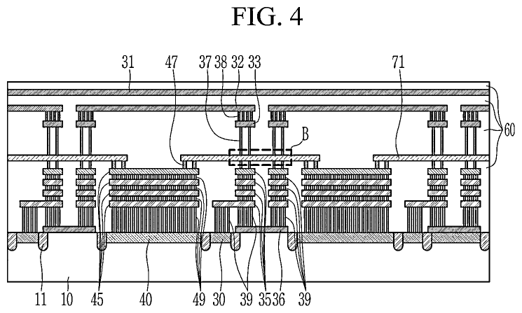

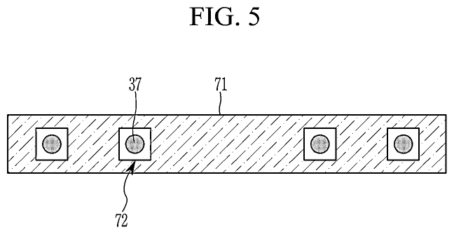

FIG. 4 illustrates a cross-sectional view of a semiconductor device according to another embodiment. FIG. 5 illustrates a layout view of portion B of FIG. 4 viewed from above.

The embodiment of FIG. 4 and FIG. 5 has a different structure for connecting the distributed plurality of portions of the chip guard 4 compared to the embodiment of FIG. 1 and FIG. 2. In the embodiments of FIG. 4 and FIG. 5, a lower polysilicon layer connection portion 71 may be disposed in parallel to or replacing the chip guard connection line 41. The lower polysilicon layer connection portion 71 may be disposed directly above the lower structure of the net chipping detection circuit 3, and may be disposed on the same layer as a common source line of the memory cell UP. The lower polysilicon layer connection portion 71 may be formed together along with the common source line. The lower polysilicon layer connection portion 71 may connect the distributed chip guards 4 through a chip guard connection via 47. Referring to FIG. 5, the lower polysilicon layer connection portion 71 may have a through hole 72, and the chipping detection circuit connection via 37 may be connected to the lower structure through the through hole 72. The through hole 72 is illustrated as a quadrangular shape, but may have a polygonal shape such as a circular or pentagonal shape.

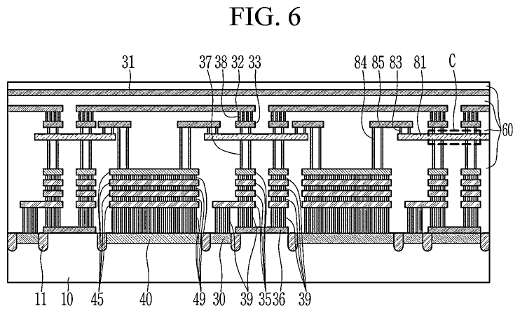

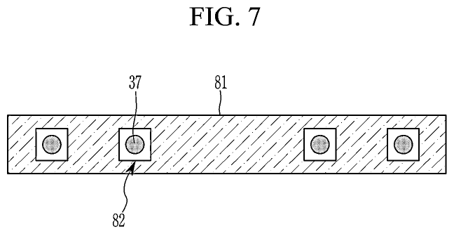

FIG. 6 illustrates a cross-sectional view of a semiconductor device according to another embodiment. FIG. 7 illustrates a layout view of portion C of FIG. 6 viewed from above.

The embodiment of FIG. 6 and FIG. 7 has a different structure for connecting the distributed plurality of portions of the chip guard 4 compared to the embodiment of FIG. 1 and FIG. 2. In the embodiments of FIG. 6 and FIG. 7, an upper polysilicon layer connection portion 81 may be disposed in parallel to or replacing the chip guard connection line 41. The upper polysilicon layer connection portion 81 may be disposed directly below the chipping detection circuit connection wire 33, and may be disposed on the same layer as a polysilicon layer that configures an upper selection gate and the like of the memory cell UP. The upper polysilicon layer connection portion 81 may be formed together with the polysilicon layer that configures the upper selection gate and the like of the memory cell UP. The upper polysilicon layer connection portion 81 may connect the distributed chip guards 4 through chip guard connection vias 83 and 84 and a chip guard connection wire 85. Referring to FIG. 7, the upper polysilicon layer connection portion 81 may have a through hole 82, and the chipping detection circuit connection via 37 may be connected to the lower structure through the through hole 82. The through hole 82 is illustrated as a quadrangular shape, but may have a polygonal shape such as pentagonal shape or a circular shape.

One or more of the elements disclosed above may be included or may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While this disclosure has been described in connection with what is presently considered to be practical embodiments, it is to be understood that the disclosure is not limited to the disclosed embodiments. On the contrary. it is intended to cover various modifications and equivalent arrangements included within the spirit and scope of the appended claims.

What is claimed is:

1. A semiconductor device comprising:
a semiconductor substrate having a first surface including a memory cell area;
a first chipping detection circuit on the first surface of the semiconductor substrate and surrounding the memory cell area; and
a chip guard on the first surface of the semiconductor substrate, wherein
a portion of the chip guard overlaps the first chipping detection circuit in a direction perpendicular to the first surface of the semiconductor substrate.

2. The semiconductor device of claim 1, wherein
the first chipping detection circuit includes a lower structure separated into a plurality of portions and an upper structure connecting the plurality of portions of the lower structure to each other.

3. The semiconductor device of claim 2, wherein
a plurality of portions in the chip guard are separated from each other and connected to each other by a chip guard connection line.

4. The semiconductor device of claim 3, wherein
the plurality of portions of the chip guard overlap the upper structure of the first chipping detection circuit in a vertical direction.

5. The semiconductor device of claim 4, wherein
an arc path diode connected between the lower structure of the first chipping detection circuit and the semiconductor substrate.

6. The semiconductor device of claim 5, wherein
the arc path diode includes an N-type doped area and a P-type doped area in the semiconductor substrate, which are near the first surface of the semiconductor substrate.

7. The semiconductor device of claim 3, wherein
the chip guard includes a chip guard doped area near the first surface of the semiconductor substrate, a chip guard wire on the chip guard doped area, and a chip guard via connecting the chip guard doped area and the chip guard wire.

8. The semiconductor device of claim 7, wherein
the chip guard doped area is doped with P-type impurities.

9. The semiconductor device of claim 3, wherein
the chip guard connection line bypasses the lower structure of the first chipping detection circuit to connect the plurality of portions of the chip guard.

10. The semiconductor device of claim 2, wherein
the lower structure of the first chipping detection circuit includes a chipping detection circuit gate on the semiconductor substrate, a plurality of chipping detection circuit wires on the chipping detection circuit gate, and a plurality of chipping detection circuit vias, and
the plurality of chipping detection circuit vias connect the chipping detection circuit gate and the plurality of chipping detection circuit wires.

11. The semiconductor device of claim 10, wherein
the upper structure of the first chipping detection circuit includes a chipping detection circuit connection wire and a chipping detection circuit connection via,
the chipping detection circuit connection wire spans between at least two of the plurality of portions of the lower structure, and
the chipping detection circuit connection via connects the lower structure and the chipping detection circuit connection wire.

12. The semiconductor device of claim 10, wherein
the chip guard includes a plurality of portions separated from each other, a polysilicon layer connection portion between the upper structure and the lower structure of the first chipping detection circuit, and a chip guard connection via connecting the polysilicon layer connection portion and the plurality of portions of the chip guard.

13. The semiconductor device of claim 10, wherein
the chip guard includes a plurality of portions separated from each other, a polysilicon layer connection portion between the upper structure and the lower structure of the first chipping detection circuit, and a chip guard connection via and a chip guard connection wire that connect the polysilicon layer connection portion and the plurality of portions of the chip guard.

14. The semiconductor device of claim 1, further comprising
a chip dam on the first surface of the semiconductor substrate, wherein
the chip dam surrounds the first chipping detection circuit and the chip guard.

15. The semiconductor device of claim 14, further comprising
a second chipping detection circuit on the first surface of the semiconductor substrate, wherein
the second chipping detection circuit is between the first chipping detection circuit and the chip guard and between the first chipping detection circuit and the chip dam.

16. A semiconductor device comprising:
a semiconductor substrate having a first surface including a memory cell area;
a first chipping detection circuit on the first surface of the semiconductor substrate and surrounding the memory cell area;
a chip guard on the first surface of the semiconductor substrate and around the memory cell area;
a chip dam on the first surface of the semiconductor substrate, the chip dam surrounding the first chipping detection circuit and the chip guard; and
a second chipping detection circuit on the first surface of the semiconductor substrate, wherein
the second chipping detection circuit is between the first chipping detection circuit and the chip guard and between the first chipping detection circuit and the chip dam,
the first chipping detection circuit includes a lower structure separated into a plurality of portions and an upper structure connecting the plurality of portions of the lower structure to each other,
the chip guard has a plurality of portions separated from each other,
the plurality of portions of the chip guard are alternately disposed with the lower structure of the first chipping detection circuit, and
the plurality of portions of the chip guard overlap the upper structure of the first chipping detection circuit in a direction perpendicular to the first surface.

17. The semiconductor device of claim 16, further comprising
an arc path diode connected between the lower structure of the first chipping detection circuit and the semiconductor substrate.

18. The semiconductor device of claim 16, wherein
the plurality of portions of the chip guard are connected to a ground voltage.

19. A semiconductor device comprising:
a first semiconductor substrate including a memory cell driving circuit;
a second semiconductor substrate bonded to the first semiconductor substrate and including a memory cell area;
a first chipping detection circuit between the first semiconductor substrate and the second semiconductor substrate and surrounding the memory cell area;
a chip guard between the first semiconductor substrate and the second semiconductor substrate, a portion of the chip guard overlapping the first chipping detection circuit in a direction perpendicular to the first semiconductor substrate and the second semiconductor substrate; and
an arc path diode connected between the first chipping detection circuit and the first semiconductor substrate, wherein
the first chipping detection circuit includes a lower structure separated into a plurality of portions and an upper structure connecting the plurality of portions of the lower structure to each other,
the lower structure of the first chipping detection circuit includes a chipping detection circuit gate on the first semiconductor substrate, a plurality of chipping detection circuit wires on the chipping detection circuit gate, and a plurality of chipping detection circuit vias connecting the chipping detection circuit gate and the plurality of chipping detection circuit wires,
the upper structure of the first chipping detection circuit includes a chipping detection circuit connection wire and a chipping detection circuit connection via,
the chipping detection circuit connection wire spans between at least two of the plurality of portions of the lower structure,
the chipping detection circuit connection via connects the lower structure and the chipping detection circuit connection wire, and
the chip guard includes a chip guard doped area near the first surface of the first semiconductor substrate, a chip guard wire on the chip guard doped area, and a chip guard via connecting the chip guard doped area and the chip guard wire.

20. The semiconductor device of claim 19, wherein
a plurality of portions of the chip guard are separated from each other,
the plurality of portions of the chip guard are connected to each other by a chip guard connection line.
